(19) United States
(12) Patent Application Publication
(10) Pub. No.: US 2012/0025169 A1
(43) Pub. Date: Feb. 2, 2012

(54) NANOSTRUCTURE ARRAY TRANSISTOR

(75) Inventors: Danny E. Mars, Los Altos, CA (US); James C. Kim, Mountain View, CA (US); Sungsoo Yi, Sunnyvale, CA (US)

(73) Assignee: SUNDIODE INC., Sunnyvale, CA (US)

(21) Appl. No.: 12/848,722

(22) Filed: Aug. 2, 2010

(51) Int. Cl. H01L 29/775; H01L 21/336; H01L 29/737

(52) U.S. Cl. 257/24; 257/14; 438/284; 257/E29.245; 257/E29.188; 257/E21.411

(57) ABSTRACT

Transistors and methods for forming transistors from groups of nanostructures are disclosed herein. The transistor may be formed from an array of nanostructures that are grown vertically on a substrate. The nanostructures may have lower, middle and upper segments that may be formed with different materials and/or doping to achieve desired effects. Collectively, the lower segments may form the source or drain, with the middle segments collectively forming the channel. Alternatively, the lower segments could collectively form the emitter or collector, with the middle segments collectively forming the base. Transistor electrodes may be planar metal structures that surround sidewalls of the nanostructures. The transistors may be Field Effect Transistors (FETs) or bipolar junction transistors (BJTs). Heterojunction bipolar junction transistors (HBTs) and high electron mobility transistors (HEMTs) are possible.

### CROSS-REFERENCE TO RELATED APPLICATIONS

The following applications are cross-referenced and incorporated by reference herein in their entirety:

U.S. patent application Ser. No. 12/796,569, entitled “Nanostructure Optoelectronic Device having Sidewall Electrical Contact,” by Kim et al., filed on Jun. 8, 2010;

U.S. patent application Ser. No. 12/796,589, entitled “Multi-Junction Solar Cell Having Sidewall Bi-Layer Electrical Interconnect,” by Kim et al., filed on Jun. 8, 2010; and

U.S. patent application Ser. No. 12/796,600, entitled “Nanostructure Optoelectronic Device with Independently Controllable Junctions,” by Kim et al., filed on Jun. 8, 2010.

### FIELD

The present disclosure relates to semiconductor devices.

### BACKGROUND

Even though the size of semiconductor devices continues to scale down, the search continues for devices and methods of fabrication that will lead to even smaller scale devices. One technology that has shown promise is sometimes referred to as “nanometer-scale” technology because of the approximate size of the structures. A variety of structures such as nanocolumns, nanowires, nanorods, and nanotubes have been used to form various devices.

As one example, nanotube transistors have been proposed. Some proposals call for a transistor using a single carbon nanotube. However, the processes for fabricating such devices may be tedious, low-yield, and not amenable to high volume manufacturing. Moreover, since the lateral dimensions of a single nanotube are small, the ability to conduct large amounts of current may be limited. This makes such devices unsuitable for some applications such as power amplifiers. Even for applications where large currents are not needed, such as logic integrated circuits, fabricating single nanotube processing may be difficult.

Some proposals call for transistor devices using groups of nanocolumns or nanotubes. In these cases, the current carrying capacity of the group is much greater than that of a single nanocolumn or nanotube. However, the fabrication processes may not be suitable for high volume manufacturing of integrated circuits.

The approaches described in this section are approaches that could be pursued, but not necessarily approaches that have been previously conceived or pursued. Therefore, unless otherwise indicated, it should not be assumed that any of the approaches described in this section qualify as prior art merely by virtue of their inclusion in this section.

### BRIEF DESCRIPTION OF THE DRAWINGS

The present disclosure is illustrated by way of example, and not by way of limitation, in the figures of the accompanying drawings and in which like reference numerals refer to similar elements and in which:

FIGS. 1A, 1B, and 1C depict embodiments of a transistor formed from an array of nanostructures.

FIG. 1D shows a top view of one embodiment of a transistor device.

FIG. 1E shows a cross section of one embodiment of a transistor.

FIG. 2 is a cross sectional drawing of one embodiment of a BJT transistor.

FIG. 3 is a cross sectional drawing of one embodiment of an FET transistor.

FIG. 4 is a flowchart depicting one embodiment of a process of fabricating a transistor that includes a nanostructure array.

FIGS. 5A, 5B, 5C, 5D, 5E, and 5F depicts show results after various steps in one embodiment of the process of FIG. 4.

FIG. 6A is a diagram of one embodiment of a high electron mobility transistor.

FIG. 6B is a top view the high electron mobility transistor of FIG. 6A.

FIG. 7A is a flowchart of a process for forming a high electron mobility transistor.

FIGS. 7B, 7C and 7D depict results of forming the HEMT after various steps of process of FIG. 7A.

### DETAILED DESCRIPTION

In the following description, for the purposes of explanation, numerous specific details are set forth in order to provide a thorough understanding of the present invention. It will be apparent, however, that embodiments may be practiced without these specific details. In other instances, well-known structures and devices are shown in block diagram form in order to avoid unnecessarily obscuring the disclosure.

Transistors and methods for forming transistors from groups of nanostructures are disclosed herein. The nanostructures may be nanocolumns, nanowires, nanorods, nanotubes, etc. In some embodiments, the nanostructures in a single transistor are grouped in an array. For example, an array of nanostructures may be grown vertically on a substrate. However, the nanostructures could also be formed from the top down by patterning a stack of planar layers and subsequent etching. Because the transistor may include an array of nanostructures, the transistor may be able to conduct a large current. Therefore, embodiments are suitable for high power applications.

The nanostructures may be formed from a variety of materials. In some embodiments, the nanostructures are formed from one or more semiconductors. In some embodiments, the nanostructures have lower, middle and upper segments that may be formed with different materials and/or doping to achieve desired effects. Electrodes may be formed as planar metal structures that surround sidewalls of the nanostructures.

Many different types of transistors may be formed. The transistors may be Field Effect Transistors (FETS) or bipolar junction transistors (BJTs). In one embodiment, the transistor is a heterojunction bipolar junction transistor (HBT). In one embodiment, the transistor is a high electron mobility transistor (HEMT).

Techniques for fabricating the transistor may use planar type processes such that cost-effective high volume manufacturing may be achieved. In some embodiments, the nanostructure array is oriented vertically with respect to the substrate. Therefore, packing density may be higher than for conventional devices. Moreover, by increasing the number of transistors per unit area, manufacturing cost may be reduced.

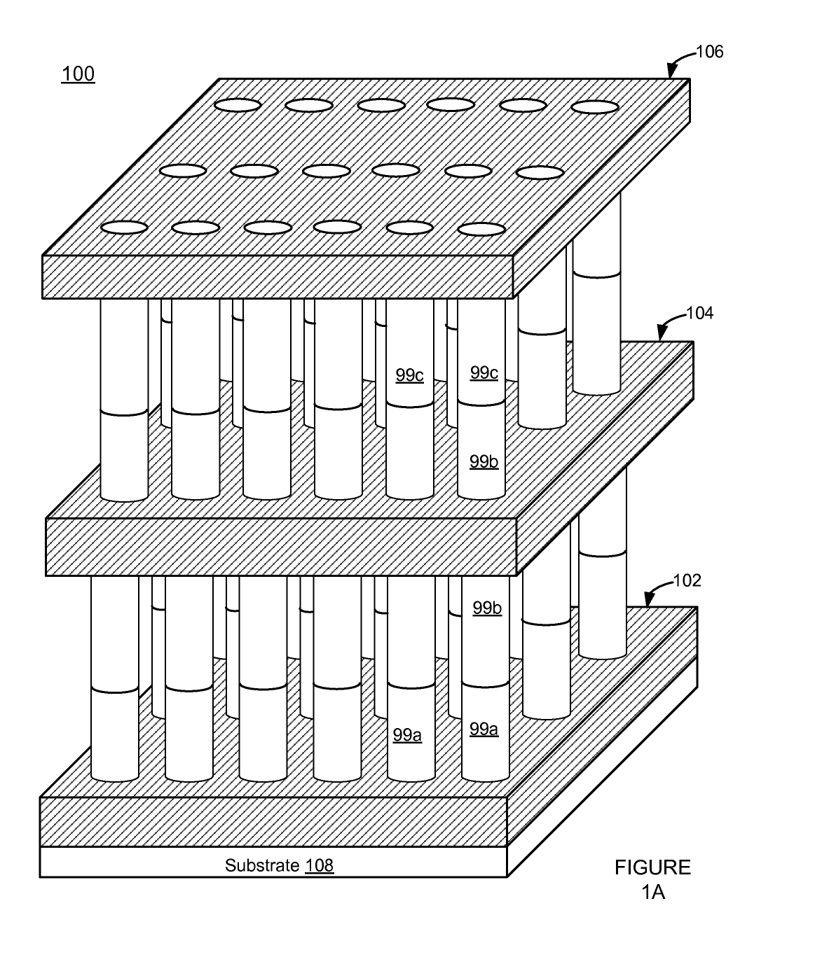

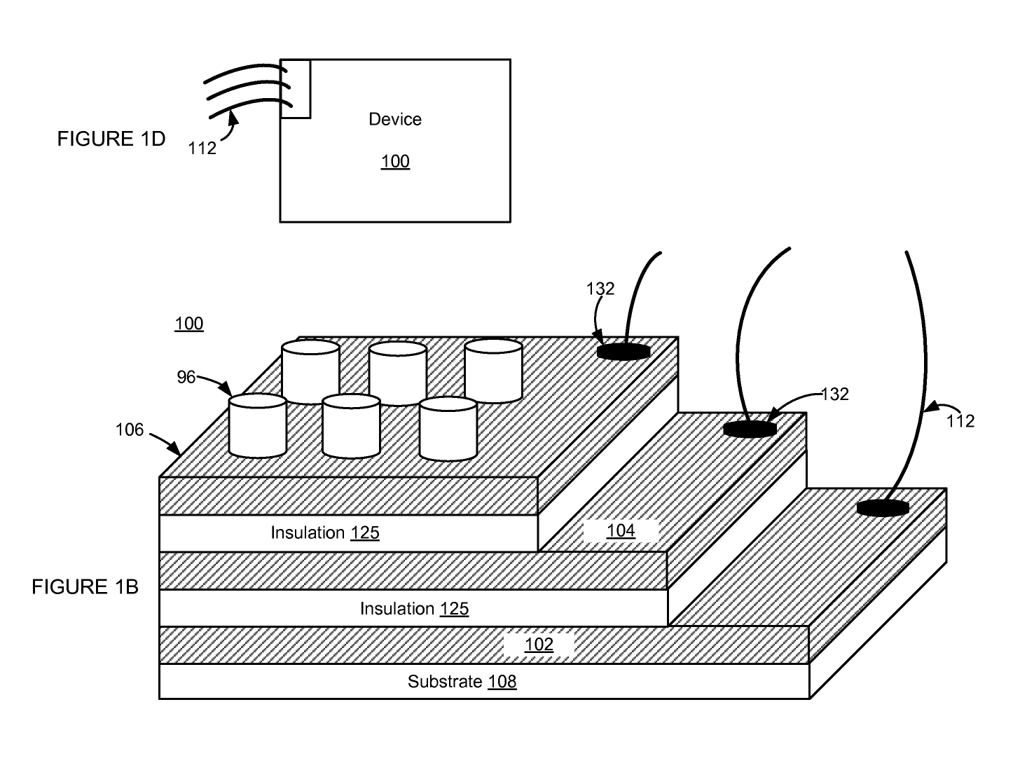

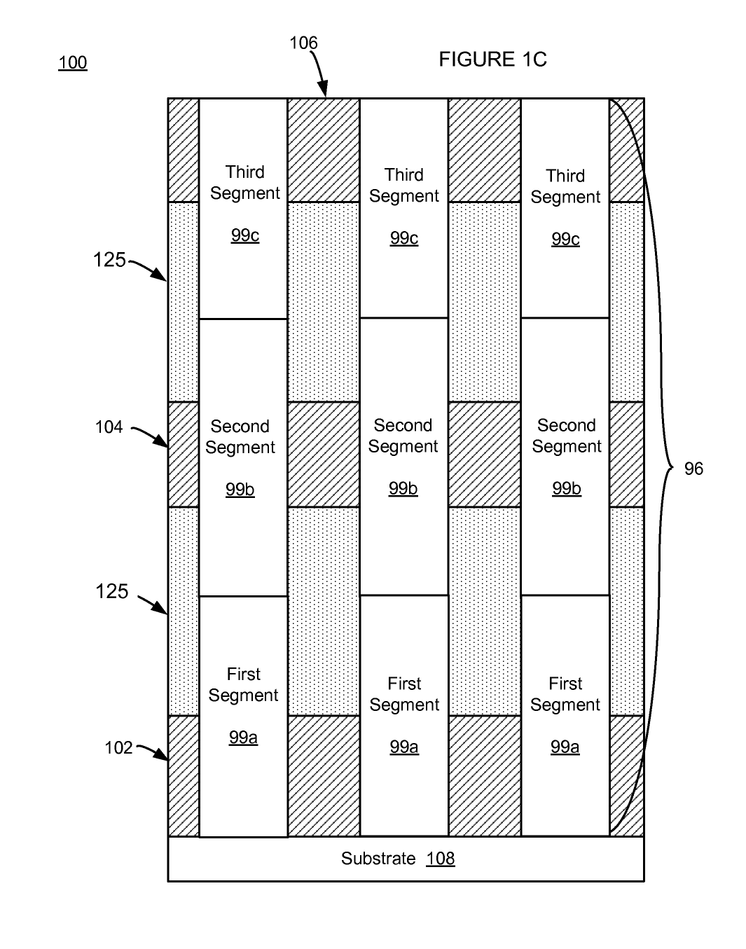

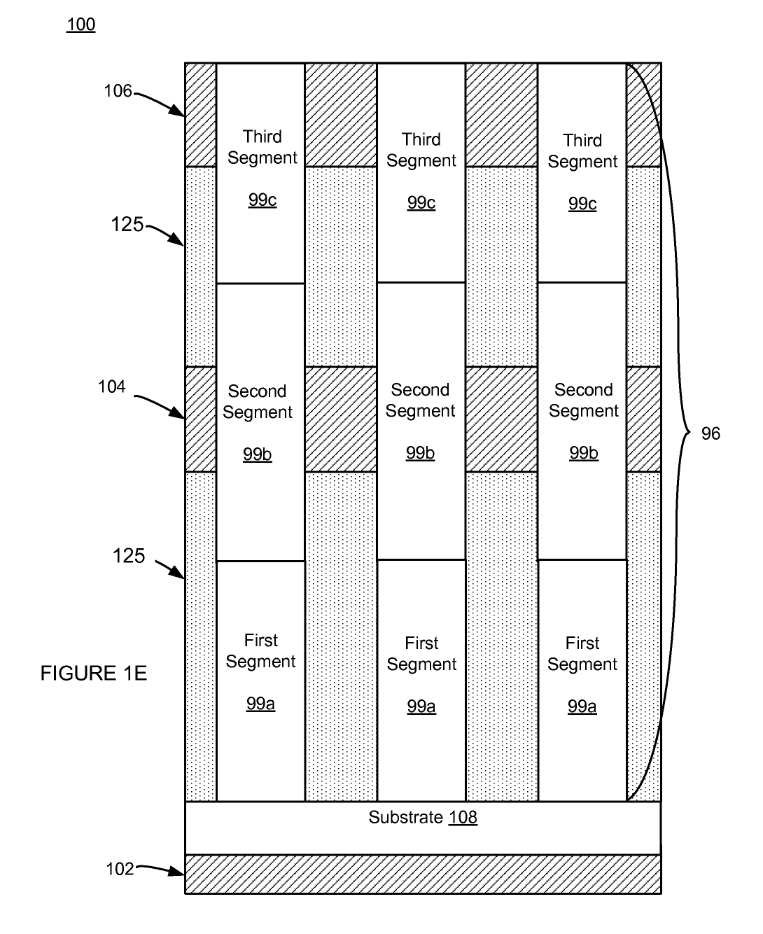

FIGS. 1A, 1B, and 1C depict embodiments of a transistor 100 formed from an array of nanostructures and will be discussed together. FIG. 1A is a perspective view of an array of nanostructures with electrodes surrounding sidewalls. FIG. 1B is a perspective view of one embodiment showing an edge of the device having contacts. FIG. 1C is a cross section of one embodiment illustrating segments in several nanostructures.

Referring to FIGS. 1A, 1B, and 1C, the example device 100 comprises an array of nanostructures 96, a first (e.g., lower) electrode 102, a second (e.g., middle) electrode 104, and a third (e.g., upper) electrode 106. The nanostructures 96 are formed over a substrate 108 in this embodiment. The nanostructures 96 have first (e.g., lower) segments 99a, second (e.g., middle) segments 99b, and third (e.g., upper) segments 99c, in this embodiment. The first electrode 102 surrounds and is in electrical contact with the first segments 99a. The second electrode 104 surrounds and is in electrical contact with the second segments 99b. The third electrode 106 surrounds and is in electrical contact with the third segments 99c. FIGS. 1B and 1C show that there may be insulation 125 between electrodes. The insulation 125 is not depicted in FIG. 1A, so as to not obscure the diagram.

As will be discussed more fully below, the segments 99 may be formed from different materials and/or doped differently to achieve different effects. For example, the lower segments 99a could serve as an emitter, the middle segments 99b as a base and the upper segments 99c as a collector. In this case, the lower electrode 102 could be an emitter electrode, the middle electrode 104 could be a base electrode, and the upper electrode 106 could be a collector electrode. Thus, the structure could form a single transistor having many nanostructures 96. Therefore, current carrying capacity may be large.

In one embodiment, the lateral width of the nanostructures 96 may range from about 5 nm-500 nm. However, nanostructures 96 may have a lesser or greater lateral width. The entire range of widths may be present in a single device. Thus, there may be considerable variance in width of individual nanostructures 96. Also note that the width of an individual nanostructure 96 may vary from top to bottom. For example, a nanostructure 96 could be narrower, or wider, at the top. Also note that nanostructures 96 are not necessarily columnar in shape. As depicted, there are spaces or gaps between the nanostructures 96. These spaces may be filled with an insulator; however, the spaces may also be left open such that there may be an air gap between nanostructures 96. The nanostructures 96 are not coalesced, in some embodiments. That is to say, that individual nanostructures 96 are not required to be joined together laterally at some level. Note that although each nanostructure 96 is depicted in FIGS. 1A-1C as completely separate from others, some of the nanostructures 96 might touch a neighbor at some point on the sidewalls.

The electrodes 102, 104, 106 may surround the sidewalls of the nanostructures 96. The electrodes 102, 104, 106 have a substantially planar structure in some embodiments. The plane may be oriented horizontally with respect to the substrate 108. However, note that the thickness of the electrodes 102, 104, 106 is allowed to vary. In some embodiments, the electrodes 102, 104, 106 are formed from metal. Example metals include, but are not limited to, nickel and aluminum.

Referring to FIG. 1B, the device 100 may have an electrical contact 132 on the edge of each electrode 102, 104, 106. Electrical leads 112 may be attached to the electrical contacts. FIG. 1D shows a top view of a transistor device 100 showing three leads 112 in one corner of the device 100. In some embodiments, an edge of the device 100 has a stair case type shape, as depicted in FIG. 1B, to accommodate the contacts 132 and leads 112. The stair case type shape of FIG. 1B may be arrived at through photolithographic techniques, such as patterning and etching. Note that the contacts 132 may be placed at a different location. For example, the contacts 132 are not required to be in a corner, or even along an edge.

Note that in FIG. 1B, the nanostructures 96 are depicted as extending above the top surface of the upper electrode 106. This is one option, but is not required. The upper electrode 106 may be more or less flush with the tops of the nanostructures 96, as depicted in FIG. 1A. In some embodiments, the upper electrode 106 is formed over the tops of the nanostructures 96. Therefore, the upper electrode 106 does not necessarily surround the sidewalls of the nanostructures. For example, the upper electrode 106 could be bonded to the tops of the nanostructures 96.

Examples of suitable materials for the substrate 108 include, but are not limited to, silicon (Si), germanium (Ge), silicon carbide (SiC), zinc oxide (ZnO), and sapphire. If the substrate 108 is either Si, or Ge, the substrate 108 may be (111)- or (100)-plane oriented, as examples. If the substrate 108 is SiC, ZnO, or sapphire the substrate 108 may be (0001) plane oriented, as one example. The substrate 108 is doped with a p-type dopant, in one embodiment. An example of a p-type dopant for Si substrates includes, but is not limited to, boron (B). The p-type doping level may be p, p⁺ or, p⁺⁺. The substrate 108 is doped with an n-type dopant, in one embodiment. Examples of n-type dopants for Si substrates include, but are not limited to, arsenic (As) and phosphorous (P). The n-type doping level may be n, n⁺ or, n⁺⁺. Note that the substrate 108 is not required for device operation. In some embodiments, the substrate 108 on which the nanostructures 96 were grown is removed (e.g., by etching), which allows for a more flexible device.

The lower electrode 102 is depicted as being in contact with the sidewalls of the nanostructures in FIG. 1C. Also, the lower electrode 102 is depicted as being above the substrate 108 in FIG. 1A-1C. However, the lower electrode 102 may be in other positions. As depicted in FIG. 1E, the lower electrode 102 is attached to the back side (or bottom) of the substrate 108. As mentioned, the substrate 108 may be doped such that it is conductive. Therefore, the lower electrode 102 is in electrical contact with the first segments 99a. If desired, portions of the substrate 108 may be etched away and filled with a conductive material, such as a metal, to allow a better conductive contact between the lower electrode 102 and the nanostructures 96. As mentioned, the substrate 108 is not an absolute requirement. In this case, the lower electrode 102 may be bonded to the nanostructures 96.

Many different types of transistors may be formed with technology disclosed herein. In some embodiments, the lower, middle and upper segments that may be formed with different materials and/or doping to achieve desired effects. The transistor may be a field effect transistor (FET) or bipolar junction transistor (BJT). In one embodiment, the transistor is a heterojunction bipolar junction transistor (HBT). In one embodiment, the transistor is a high electron mobility transistor (HEMT).

For example, a BJT may be formed using any of the devices of FIG. 1A-1E. In a BJT, the upper segments 99c may collectively form the emitter, the middle segments 99b may collectively form the base, and the lower segments 99a may collectively form the collector. The emitter and collector could be switched. Each electrode 102, 104, 106 may form an Ohmic contact with the nanostructures 96. Electrode 102 may thus be a collector electrode; electrode 104 may be a base electrode; and electrode 106 may thus be an emitter electrode.

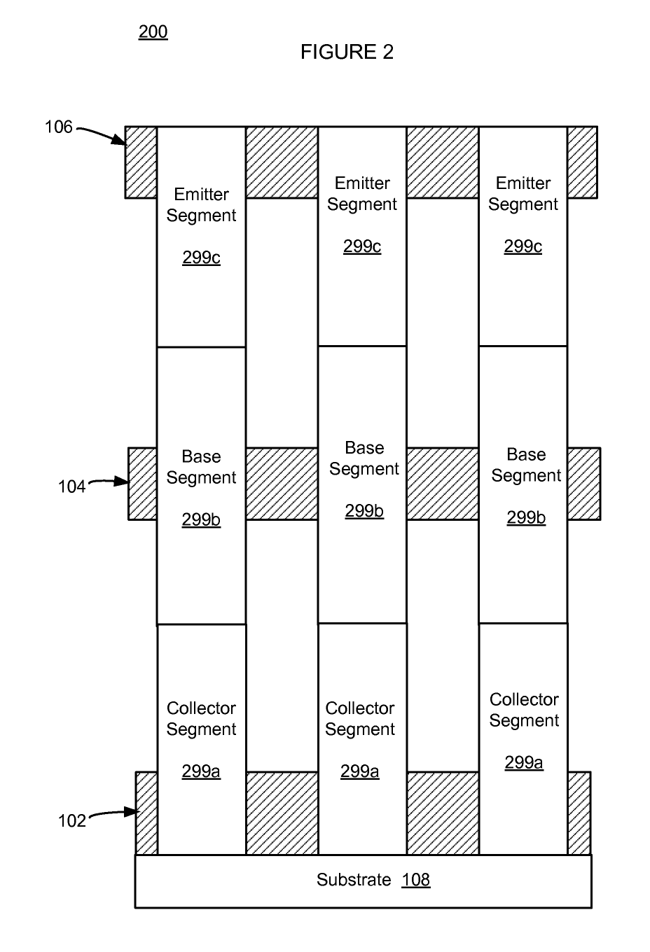

FIG. 2 is a cross sectional drawing of one embodiment of a BJT 200. The BJT 200 may be formed using any of the devices of FIG. 1A-1E. In the BJT 200 of FIG. 2, each nanostructure 96 forms a portion of the collector, a portion of the emitter, and a portion of the base. This is represented by referring to the collector segments 299a, base segments 299b, and emitter segments 299c. Thus, a collector segment 299a corresponds to a first segment 99a, a base segment 299b corresponds to a second segment 99b, and an emitter segment 299c corresponds to a third segment 99c. Note that the collector 299a and emitter segments 299c could be switched. Segments 299a could be referred to as first collector/emitter segments. Likewise, segments 299c could be referred to as second collector/emitter segments. As noted above, collectively the collector segments 299a form the transistor collector, collectively the base segments 299b form the transistor base, and collectively the emitter segments 299c form the transistor emitter. Since there may be many nanostructures 96, the BJT 200 may be suitable for high current applications.

In one embodiment, the collector segments 299a are formed from (Al)GaN. The collector segments 299a may be doped with an n-type donor such as Si. In the present embodiment, the emitter segments 299c may be formed from (Al)GaN. The emitter segments 299a may be doped with an n-type donor such as Si. In the present embodiment, the base segments 299b may be formed from (In)GaN. The base segments 299a may be doped with a p-type donor such as Mg. However, different dopants could be used. Moreover, the nanostructures 96 could be formed with other materials.

With the foregoing example materials, the transistor 200 is a heterojunction transistor. For example, the material for the base has a different band gap than the materials for the collector and emitter. However, collector segments 299a, base segments 299b and emitter segments 299c could each be formed from materials having the same band gap. Thus, a heterojunction is not required. As mentioned above, a pnp transistor could be formed instead.

As mentioned above, the electrodes 102, 104, 106 may form an Ohmic contact with the nanostructures of the BJT 200. Given the example materials, the first electrode 102 and third electrode 106 may be formed from a metal that makes good Ohmic contact with (Al)GaN. The second electrode 104 may be formed from a metal that makes good Ohmic contact with (In)GaN. In some embodiments, the electrodes 102, 104, 106 that contact the n-type semiconductor regions may be made of a suitable material to form an Ohmic contact with an n-type semiconductor. Electrodes 102, 104, 106 that contact p-type semiconductor regions may be made of a suitable material to form an Ohmic contact with a p-type semiconductor. For example, aluminum may form an Ohmic contact with nanostructures formed from n-doped nitride semiconductors. Nickel may form an Ohmic contact with nanostructures formed from p-doped nitride semiconductors. Note that the first electrode 102 may also be referred to as a first emitter/collector electrode and the third electrode 106 may also be referred to as a second emitter/collector electrode.

Note that because of the compliant nature of nanocolumn growth, the indium (In) mole fraction of the base can be made high. The activation energy of the acceptor may be decreased as the In composition is increased; therefore, there may a great improvement in the conductivity of Mg-doped InGaN material of the base. This improvement in base conductivity may greatly improve overall device performance.

As noted, an FET may be formed using any of the devices of FIG. 1A-1E. In an FET, the upper segments 99c may collectively form the source, the middle segments 99b collectively may form the channel, and the lower segments 99a may collectively form the drain. The source and drain could be switched. The first and third electrodes 106 and 102 may form an Ohmic contact with the nanostructures 96. Electrode 102 may thus be a drain electrode, and electrode 106 may be a source electrode. Electrode 104 may form a Schottky contact with the middle segments (e.g., channel). Thus, electrode 104 may function as the gate.

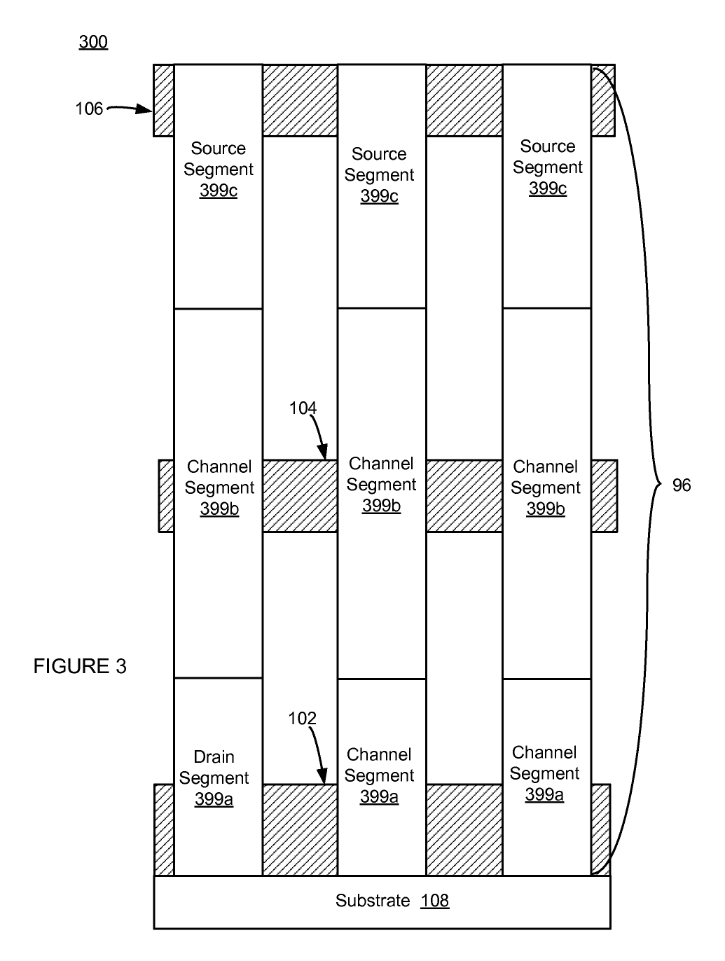

FIG. 3 is a cross sectional drawing of an FET 300. The FET 300 may be formed using any of the devices of FIG. 1A-1E. In the FET 300 of FIG. 3, each nanostructure 96 forms a portion of the source, a portion of the channel, and a portion of the drain. This is represented by referring to the source segments 399a, channel segments 399b, and drain segments 399c. Thus, a drain segment 399a corresponds to a first segment 99a, a channel segment 399b corresponds to a second segment 99b, and a source segment 399c corresponds to a third segment 99c. Note that the drain 399a and source segments 399c could be switched. Segments 399a could be referred to as first source/drain segments. Likewise, segments 399c could be referred to as second source/drain segments. As noted above, collectively the drain segments 399a form the transistor drain, collectively the channel segments 399b form the transistor channel, and collectively the source segments 399c form the transistor source.

In one embodiment, the drain segments 399a are formed from GaN. The drain segments 399a may be doped with an n-type donor such as Si. In the present embodiment, the source segments 399c may be formed from GaN. The source segments 399a may be doped with an n-type donor such as Si. In the present embodiment, the channel segments 399b may be formed from GaN. The channel segments 399b may be intrinsic or unintentionally doped or doped (e.g., n-type). In the present embodiment, GaN is used for all segments; however, the segments are not required to all be formed from the same material. Also, a material other than GaN may be used. Note that the source and drain could be p-doped instead.

As mentioned above, the lower and upper electrodes 102, 106 may form an Ohmic contact with the nanostructures of the FET 300. However, the middle electrode 104 may form a Schottky contact with the nanostructures. Note that the first electrode 102 may also be referred to as a first source/drain electrode and the third electrode 106 may also be referred to as a second source/drain electrode.

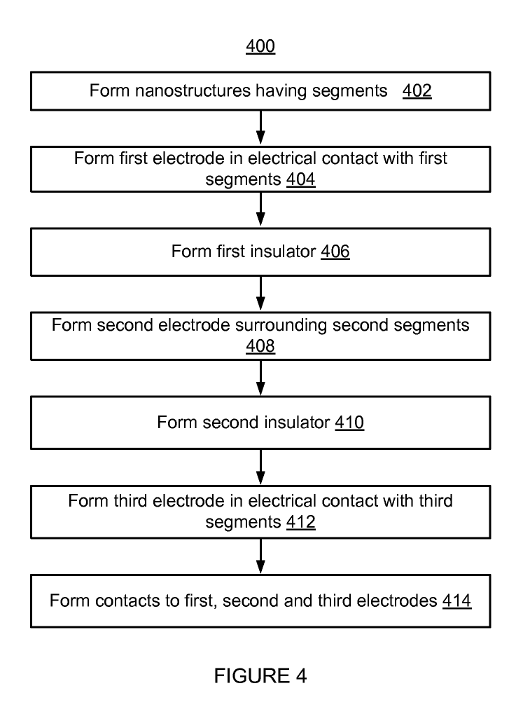

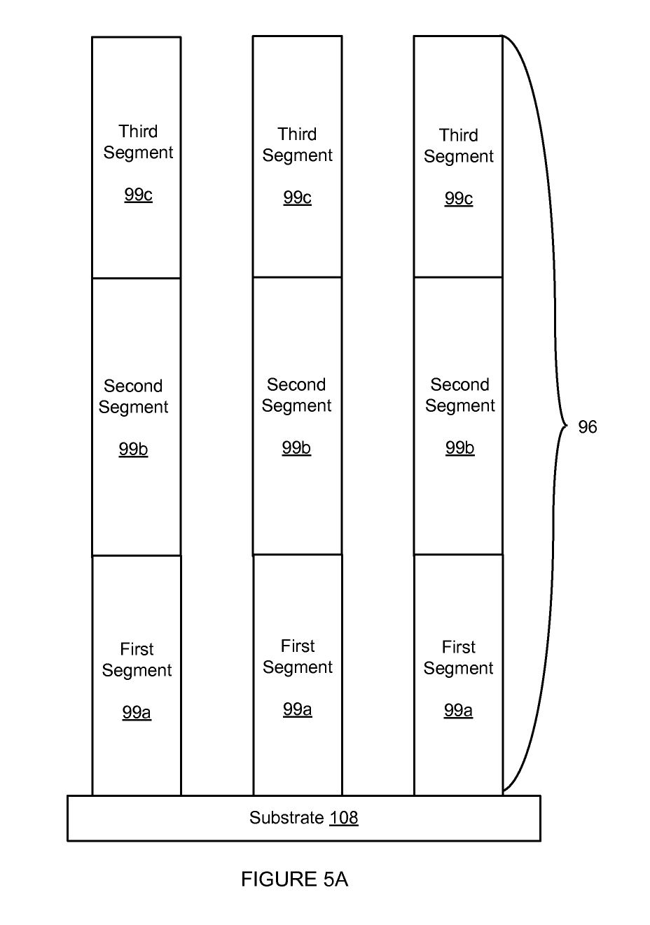

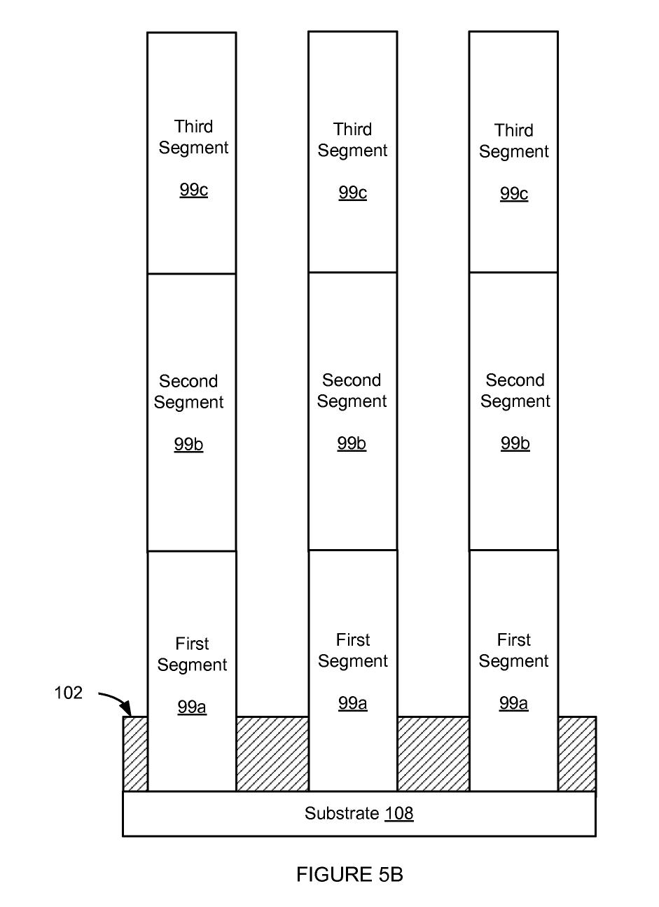

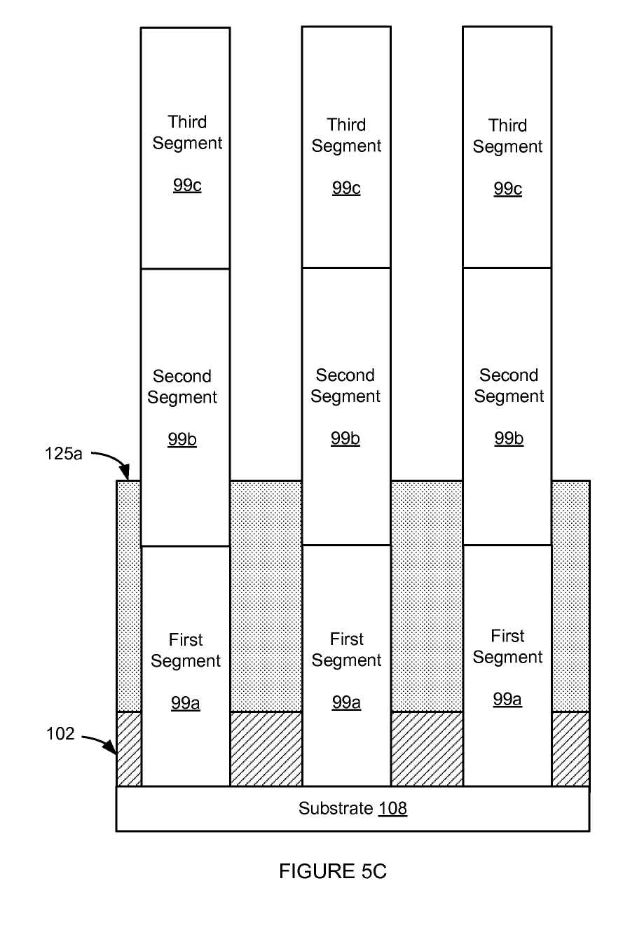

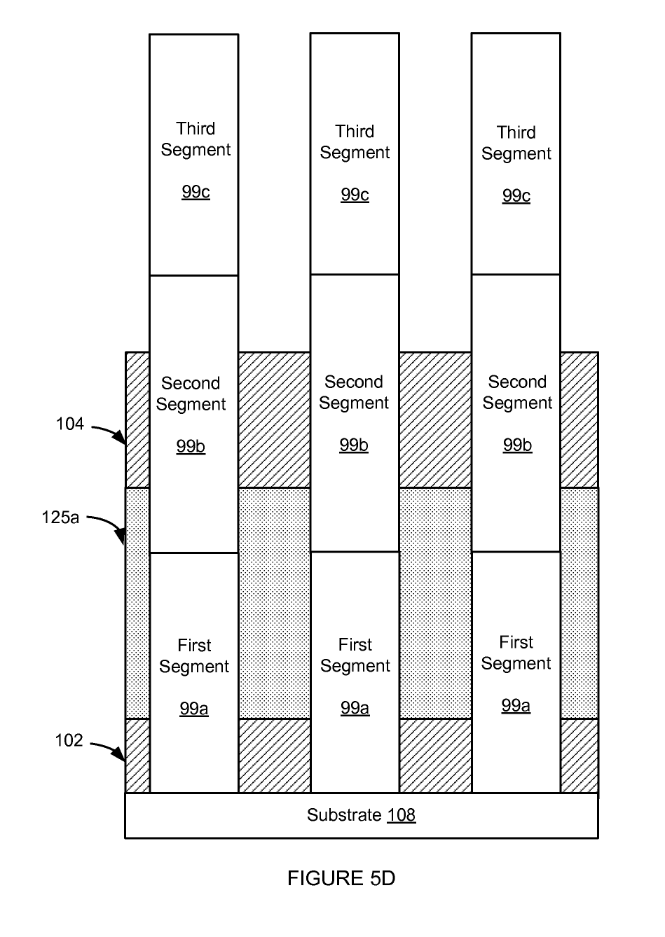

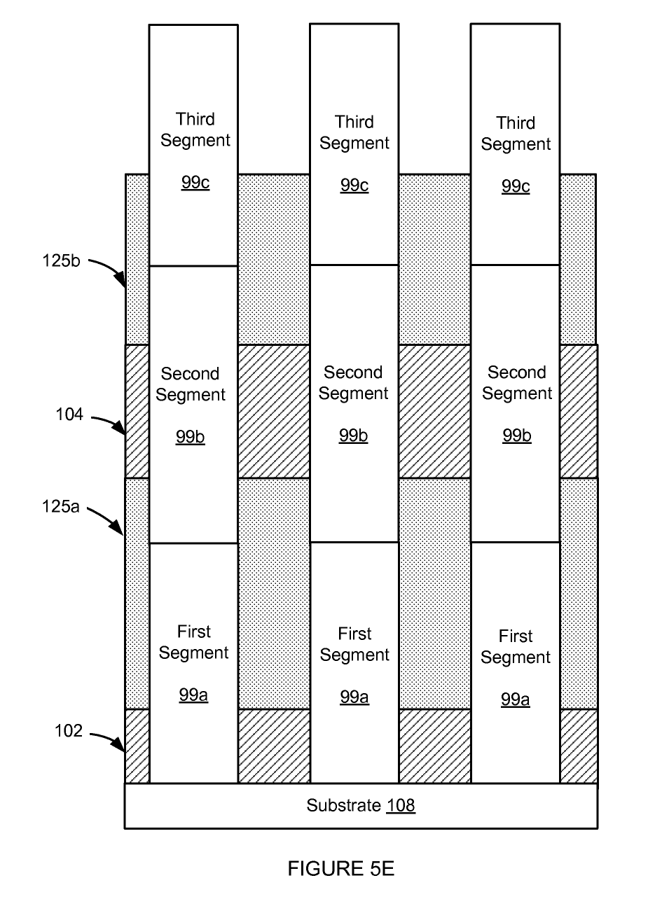

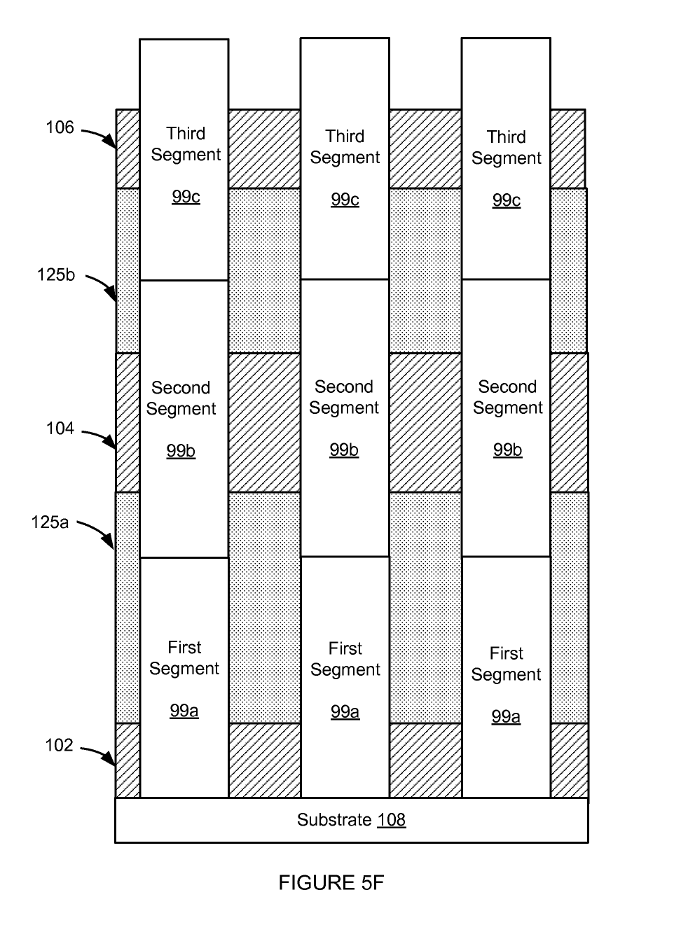

FIG. 4 is a flowchart depicting one embodiment of a process 400 of fabricating a transistor that includes a nanostructure array. Process 400 may be used to fabricate a device such as those depicted in FIGS. 1A-1E, 2, and 3. However, process 400 is not limited to fabricating those devices. Process 400 may be used to form FETs or BJTs, for example. Not all process steps are depicted so as to simplify the explanation. FIGS. 5A-5F show results after various steps in one embodiment of process 400. FIGS. 5A-5F show a side perspective view showing a cutaway portion of a few nanostructures 96.

In step 402, nanostructures 96 having segments 99 are formed. In some embodiments first, second and third segments 99a, 99b, 99c are formed in the nanostructures 96. As noted these may be drain, channel, and source segments (399a, 399b, 399c) or collector, base and emitter segments (299a, 299b, 299c). However, a different number of segments could be formed. In one embodiment, an array of nanostructures 96 are grown vertically on a substrate 108. The nanostructures 96 may be grown either by self-assembly or by patterned growth using epitaxial growth techniques such as metalorganic chemical vapor deposition, molecular beam epitaxy and hydride vapor phase epitaxy. In patterned growth, a portion of the substrate surface which is not covered by mask material such as SiO₂, SiNₓ, or metal is exposed to serve as nucleation sites for the nanostructures 96. The nanostructures 96 may also be grown using nanoparticles such as gold (Au) and nickel (Ni), which may act as nucleation sites for the nanostructures 96.

In some embodiments, the nanostructures 96 are formed by patterning and etching. For example, one or more planar layers of material for the nanostructures 96 is deposited. Each layer may be doped appropriately in situ or by implantation. After depositing and doping all layers, photolithography may be used to pattern and etch in order to form the nanostructures 96 having segments.

In some embodiments, step 402 includes forming the different segments having different materials from each other. However, each segment may be formed from the same material. In some embodiments, forming the different segments includes doping the nanostructures 96 with one or more impurities. That is, different doping may be used in the different segments. Intrinsic segments may also be formed. Note that the substrate 108 may be doped prior to forming the nanostructures 96. FIG. 5A depicts results after step 402. Specifically, a few nanostructures 96 out of an array of nanostructures 96 are depicted over a substrate 108. Each nanostructure 96 has a first segment 99a, second segment 99b, and third segment 99c. The materials and doping for the segments is selected according to the type of transistor that is being formed. Therefore, the first segment 99a, second segment 99b, and third segment 99c could be drain, channel, and source segments (399a, 399b, 399c) or collector, base and emitter segments (299a, 299b, 299c).

In step 404, a first (or lower) electrode 102 that is in electrical contact with the first segments 99a is formed. In one embodiment, the lower electrode 102 surrounds the sidewalls of the nanostructures 96. In such embodiments, the lower electrode 102 may be formed by depositing a material over the substrate 108 (after the nanostructures 96 have been formed) and etching back the material. The material may be metal. In patterned growth employing conductive material (such as metal) as a mask material, the mask layer may serve as the lower electrode 102. However, it is not required that the lower electrode 102 surrounds the sidewalls of the nanostructures 96. FIG. 5B depicts results after step 404 for one embodiment. For some embodiments, the lower electrode 102 may be formed below the substrate 108. As noted above, the lower electrode 102 may function as a source (or drain) electrode, in one embodiment. In another embodiment, the lower electrode 102 may function as a collector (or emitter) electrode.

In step 406, a first insulator is formed around the sidewalls of the nanostructures 96 above the lower electrode 102. In one embodiment, spin-on-glass (SOG) is applied. In one embodiment, silicon dioxide is deposited. In another embodiment, photoresist is added. Note that more than one type of material could be used. For example, layers of different materials could be deposited or a single region could include multiple materials. After depositing, the insulator may be etched back to a suitable level. FIG. 5C depicts results after step 406 showing the second insulator 125a surrounding the nanostructure sidewalls. The insulator 125a covers the sidewalls of the first segments 99a (that are not covered by the first electrode 102) and also covers the lower portions of the sidewalls of the second segments 99b.

In step 408, a second (or middle) electrode 104 that surrounds the sidewalls of the second segments 99b is formed. The middle electrode 104 may be formed by depositing a material over the insulator 125a and etching back the material. The material may be metal. In some embodiments, the middle electrode 104 forms an Ohmic contact with the second segments 99b. In some embodiments, the middle electrode 104 forms a Schottky contact with the second segments 99b. FIG. 5D depicts results after step 408 for one embodiment. As noted above, the middle electrode 104 may serve as a gate electrode, in one embodiment. In another embodiment, the middle electrode 104 may serve as a base electrode.

In step 410, a second insulator is formed around the sidewalls of the nanostructures 96 above the middle electrode 104. In one embodiment, spin-on-glass (SOG) is applied. In one embodiment, silicon dioxide is deposited. In another embodiment, photoresist is added. Note that more than one type of material could be used. For example, layers of different materials could be deposited or a single region could include multiple materials. After depositing, the insulator may be etched back to a suitable level. FIG. 5E depicts results after step 410 showing the second insulator 125b surrounding the nanostructure sidewalls. The insulator 125b covers the sidewalls of the second segments 99b (that are not covered by the second electrode 104) and also covers the lower portions of the sidewalls of the third segments 99c.

In step 412, a third (or upper) electrode 106 that is in electrical contact with the third segments 99c is formed. The upper electrode 106 may surround the sidewalls of the third segments 99c. The upper electrode 106 may be formed by depositing a material over the insulator 125b and etching back the material. The material may be metal. FIG. 5F depicts results after step 412 for one embodiment. As noted above, the upper electrode 106 may serve as a source (or drain) electrode, in one embodiment. In another embodiment, the upper electrode 106 may serve as an emitter (or collector) electrode.

In step 414, electrical contacts 132 are formed to the first, second, and third electrodes 102, 104, 106. In one embodiment, patterning and etching is performed to remove a portion of the third electrode 106 and the second insulation 125b to expose a portion of the second electrode 104. Likewise, patterning and etching may be performed to remove a portion of the second electrode 104 and the first insulation 125a to expose a portion of the first electrode 102. A stair case type structure may be formed, as depicted in FIG. 1B. Electrical contacts 132 may be formed on the exposed first 102, second 104, and third electrodes 106. Electrical leads 112 may be attached to the electrical contacts 132. FIG. 1B depicts an example device 100 having electrical contacts 132 and leads 112.

In one embodiment, the transistor is a high electron mobility transistor (HEMT). A HEMT may have a high energy bandgap region adjacent to the channel (which may have a lower bandgap than the high energy bandgap region). Free electrons may be able to transfer from the high bandgap material into the lower bandgap channel. In this way, high carrier concentration and high electron mobility can be achieved simultaneously. This leads to overall higher device performance.

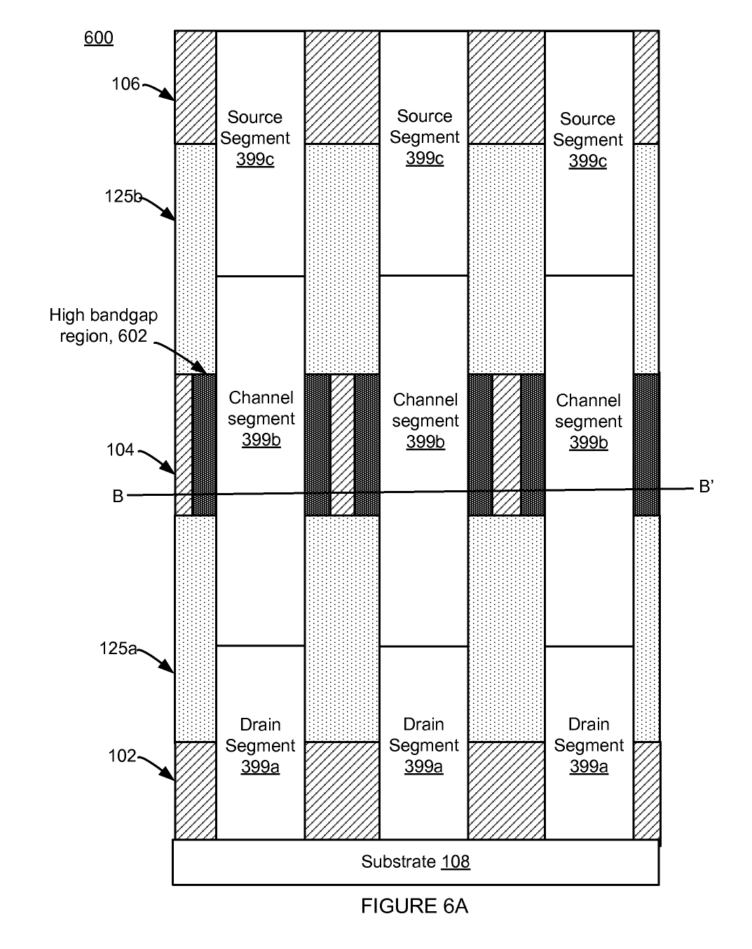

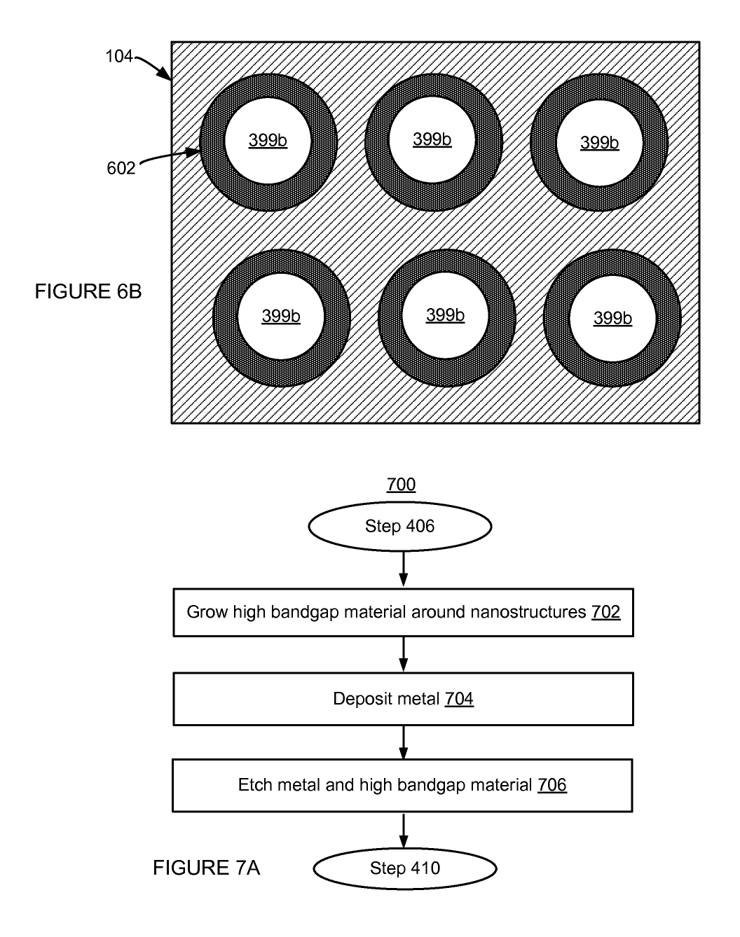

FIG. 6A is a diagram of one embodiment of a HEMT 600. The HEMT 600 is similar to the FET of FIG. 3; however, the HEMT has high bandgap regions 602 surrounding the channel segments 399b. FIG. 6B shows a cross sectional of the HEMT taken along line B-B′ of FIG. 6A. FIG. 6B shows the high bandgap regions 602 surrounding the channel segments 399b. The second electrode 104 (e.g., gate electrode) surrounds the high bandgap regions 602 (as well as the channel segments 399b). The channel segments 399b may be formed from GaN. The high bandgap regions 602 may be formed from AlGaN. However, other materials may be used. In general, the high bandgap regions 602 should have a higher energy bandgap than the channel segments 399b.

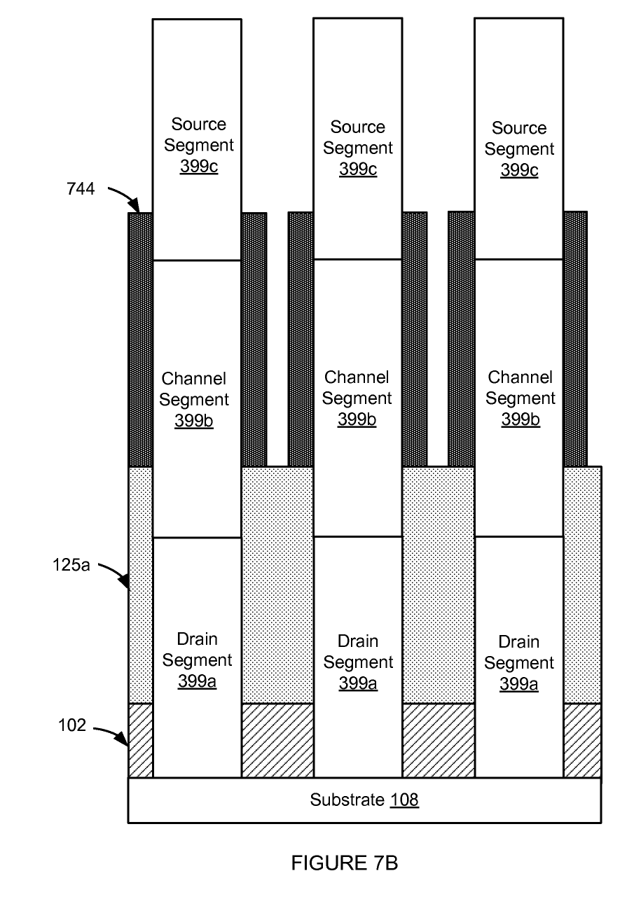

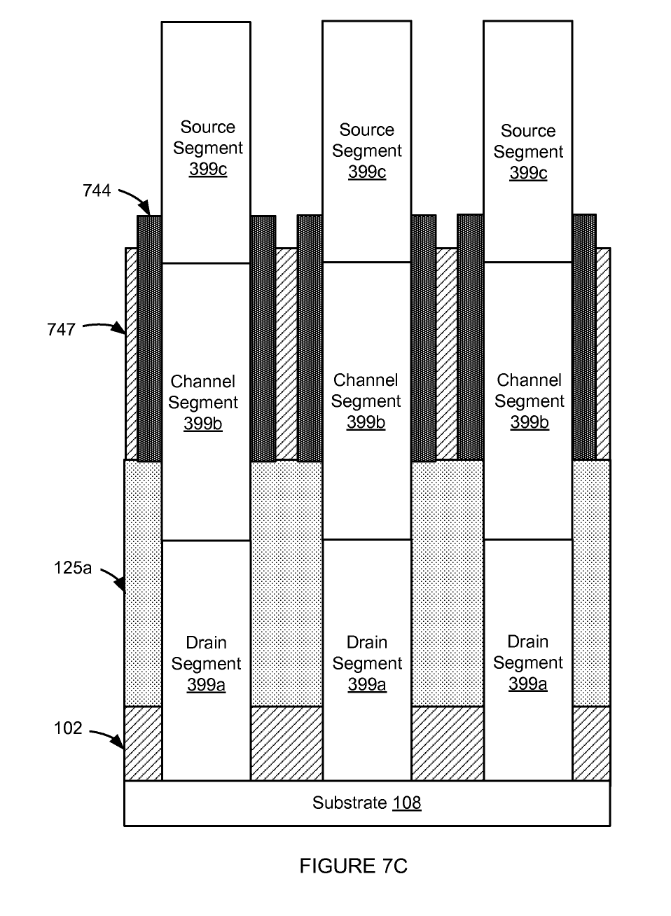

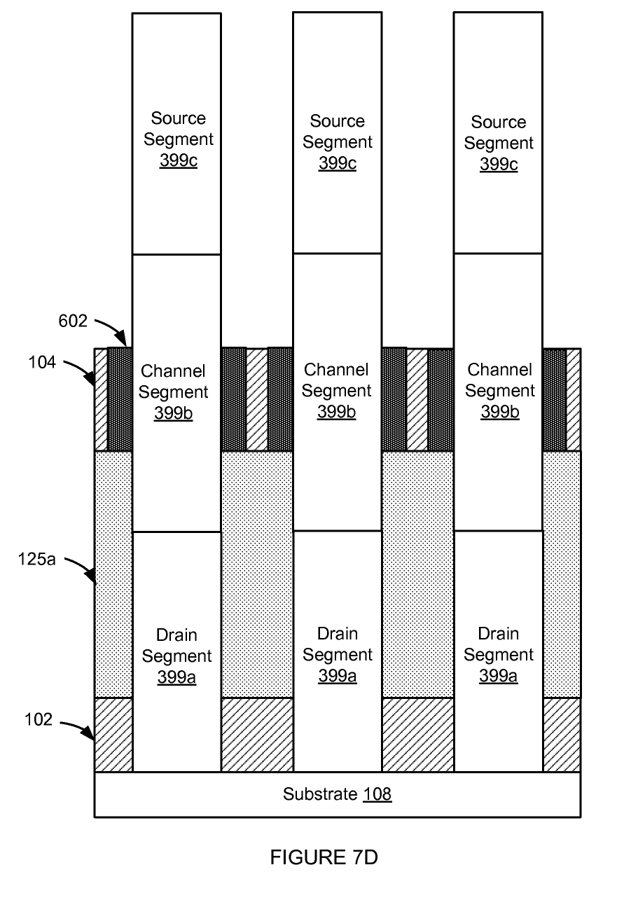

FIG. 7A is a flowchart of a process 700 for forming a HEMT. The process 700 may be used to form a device such as the embodiment in FIG. 6A-6B. FIGS. 7B-7D depict results of forming the HEMT after various steps of process 700. Process 700 may begin similar to process 400 by forming nanostructures 96, forming a first electrode 102, and forming a first insulator 125a. Therefore, process 700 may begin after step 406 of process 400. When forming the nanostructures 96, the drain and source segments 399a, 399b may be doped appropriately for the source and drain. The channel segments 399b may be grown from a material that has a lower bandgap than the high bandgap material to be formed later. As one example, at least the channel segments 399b of the nanostructures 96 may be formed from GaN, which is suitable if the high bandgap material is AlGaN. The first insulator 125a should be formed from a material that is able to withstand the growth temperature of the high bandgap material. For example, spin-on-glass (SOG) should be able to withstand growth temperatures for AlGaN.

Next, material for the high bandgap region 602 is grown around the nanostructures 96 at least for some portion of the channel segments 399b, in step 702. As one example, AlGaN is grown. In one embodiment, the mole fraction of Al is greater than 0.2. However, the mole fraction may be less than 0.2. FIG. 7B depicts results after step 702. Note that the first insulator 125a may surround the lower portions of the channel segments 399b. At this point the material 744 that will be used to form the high bandgap region may surround a portion of the source segments 399c, but that is not required.

In step 704, metal is deposited for the second electrode 104. FIG. 7C depicts results after step 704 showing metal 747 around the material 744 that will be used to form the high bandgap region 602. In step 706, the metal 747 and the material 744 for high bandgap region 602 are etched back using appropriate etchants. FIG. 7D depicts results after step 706 showing that the second electrode 104 and the high bandgap region 602 have been formed. Next, process 400 may be resumed at step 410 to form the second insulator 125b, third electrode 106 and contacts.

One embodiment includes a transistor comprising an array of nanostructures, wherein nanostructures in the array of nanostructures include first segments, second segments, and third segments. The second segments are between the first and third segments. The transistor further includes a first electrode in electrical contact with the first segments of the nanostructures; a second electrode surrounding ones of the second segments of the nanostructures; and a third electrode in electrical contact with the third segments of the nanostructures.

One embodiment includes a method of forming a transistor comprising: forming an array of nanostructures, wherein nanostructures in the array of nanostructures include first segments, second segments, and third segments, the second segments are between the first and the third segments; forming a first electrode in electrical contact with the first segments of the nanostructures; forming a second electrode surrounding ones of the second segments of the nanostructures; and forming a third electrode in electrical contact with the third segments of the nanostructures.

One embodiment includes a field effect transistor comprising an array of nanostructures, wherein the nanostructures include lower segments, middle segments, and upper segments. The upper segments and the lower segments may be doped with a material having a first type of conductivity. The transistor may also include a first source/drain electrode in electrical contact with the lower segments of the array of nanostructures; a gate electrode surrounding ones of the middle segments of the plurality of nanostructures; and a second source/drain electrode in electrical contact with the upper segments.

One embodiment includes a bipolar junction transistor comprising an array of nanostructures, wherein the nanostructures having lower segments, middle segments, and upper segments. The upper segments and the lower segments may be doped with a material having a first type of conductivity; the middle segments may be doped with a material having a second type of conductivity. The transistor may also include a first emitter/collector electrode in electrical contact with the lower segments of the array of nanostructures; a base electrode in electrical contact with the middle segments of the plurality of nanostructures; and a second emitter/collector electrode in electrical contact with the upper segments.

In the foregoing specification, several examples have been provided in which example shapes of nanostructures having been depicted for illustrative purposes. However, other shapes are possible. Thus, embodiments are not to be limited to columnar shapes, for example.

In the foregoing specification, embodiments of the invention have been described with reference to numerous specific details that may vary from implementation to implementation. Thus, the sole and exclusive indicator of what is the invention, and is intended by the applicants to be the invention, is the set of claims that issue from this application, in the specific form in which such claims issue, including any subsequent correction. Any definitions expressly set forth herein for terms contained in such claims shall govern the meaning of such terms as used in the claims. Hence, no limitation, element, property, feature, advantage or attribute that is not expressly recited in a claim should limit the scope of such claim in any way. The specification and drawings are, accordingly, to be regarded in an illustrative rather than a restrictive sense.

What is claimed is:

1. A transistor comprising:
an array of nanostructures, wherein nanostructures in the array of nanostructures include first segments, second segments, and third segments, the second segments are between the first and third segments;
a first electrode in electrical contact with the first segments of the nanostructures;
a second electrode surrounding ones of the second segments of the nanostructures; and
a third electrode in electrical contact with the third segments of the nanostructures.

2. The transistor of claim 1, wherein the transistor is a field effect transistor.

3. The transistor of claim 1, wherein the transistor is a bipolar junction transistor.

4. The transistor of claim 1, wherein the first segments and the third segments are doped with a material having a first type of conductivity.

5. The transistor of claim 4, wherein the second segments are doped with a material having a second type of conductivity that is opposite the first type of conductivity.

6. The transistor of claim 4, wherein the second segments are not intentionally doped.

7. The transistor of claim 1, wherein the array of nanostructures is aligned perpendicular with respect to the surface of a substrate.

8. The transistor of claim 1, wherein the first, the second, and the third electrodes have a planar structure that is aligned horizontally with respect to the surface of a substrate.

9. The transistor of claim 1, wherein the third electrode surrounds sidewalls of ones of the nanostructures.

10. The transistor of claim 9, wherein the first electrode surrounds sidewalls of ones of the nanostructures.

11. The transistor of claim 1, wherein the first segments are either a drain or a source of the transistor, the second segments form a channel of the transistor, and the third segments are either a source or a drain of the transistor.

12. The transistor of claim 1, wherein the first segments are either an emitter or a collector of the transistor, the second segments form a base of the transistor, and the third segments are either a collector or an emitter of the transistor.

13. The transistor of claim 1, wherein the second electrode forms a Schottky contact with the second segments of the nanostructures.

14. The transistor of claim 1, wherein the first, the second and the third electrodes form an Ohmic contact with the array of nano structures.

15. The transistor of claim 1, wherein the first, the second and the third electrodes include metal.

16. The transistor of claim 1, wherein the nanostructures include a nitride semiconductor.

17. The transistor of claim 1, further comprising a high bandgap region at least partially around ones of the second segments, the high bandgap region is between the second electrode and the second segments, the high bandgap region includes a first material having a first bandgap, the second segments include a second material having a second bandgap, the first bandgap is greater than the second bandgap.

18. A method of forming a transistor comprising:
forming an array of nanostructures, including forming first segments, second segments, and third segments in the nanostructures, the second segments are between the first and the third segments;
forming a first electrode in electrical contact with the first segments of the nanostructures;
forming a second electrode surrounding ones of the second segments of the nanostructures; and
forming a third electrode in electrical contact with the third segments of the nanostructures.

19. The method of claim 18, wherein forming an array of nanostructures includes growing the nanostructures vertically on a substrate.

20. The method of claim 18, wherein the forming the first, the second, and the third electrodes includes forming planar structures that are horizontal to a substrate.

21. The method of claim 18, wherein forming the first, the second, and the third electrodes includes:
forming a first layer of metal around sidewalls of the nanostructures,
forming a second layer of metal around the sidewalls of the nanostructures; and
forming a third layer of metal around the sidewalls of the nanostructures.

22. The method of claim 21, further comprising:
forming a first layer of insulation over the first layer of metal and around the sidewalls of the nano structures; and
forming a second layer of insulation over the second layer of metal and around the sidewalls of the nanostructures.

23. The method of claim 18, wherein the forming an array of nanostructures includes doping the first segments and the third segments with a material having a first type of conductivity.

24. The method of claim 23, wherein the forming an array of nanostructures includes doping the second segments with a material having a second type of conductivity that is opposite the first type.

25. The method of claim 18, wherein the forming an array of nanostructures includes not intentionally doping the second segments.

26. The method of claim 18, wherein forming the second electrode includes forming a Schottky contact with the second segments.

27. The method of claim 18, further comprising forming a high bandgap region at least partially around the ones of the second segments, wherein the second electrode is formed around the high bandgap region, wherein the high bandgap region is formed from a first material having a first bandgap, wherein the second segments are formed from a second material having a second bandgap, the first bandgap is greater than the second bandgap.

28. A field effect transistor comprising:
an array of nanostructures, the nanostructures having lower segments, middle segments, and upper segments, the upper segments and the lower segments are doped with a material having a first type of conductivity;
a first source/drain electrode in electrical contact with the lower segments of the array of nano structures;
a gate electrode surrounding ones of the middle segments of the plurality of nanostructures; and
a second source/drain electrode in electrical contact with the upper segments.

29. The field effect transistor of claim 28, wherein:
the middle segments are not intentionally doped.

30. The field effect transistor of claim 28, further comprising a high bandgap region between ones of the second segments and the gate electrode, the high bandgap region includes a first material having a first bandgap, the second segments include a second material having a second bandgap, the first bandgap is greater than the second bandgap.

31. The field effect transistor of claim 28, wherein the second source/drain electrode surrounds ones of the upper segments of the plurality of nanostructures.

32. The field effect transistor of claim 31, wherein the first source/drain electrode surrounds ones of the lower segments of the plurality of nanostructures.

33. The field effect transistor of claim 28, wherein the gate electrode forms a Schottky contact with the middle segments.

34. A bipolar junction transistor comprising:
an array of nanostructures, the nanostructures having lower segments, middle segments, and upper segments, the upper segments and the lower segments are doped with a material having a first type of conductivity, the middle segments are doped with a material having a second type of conductivity;
a first emitter/collector electrode in electrical contact with the lower segments of the array of nanostructures;
a base electrode in electrical contact with the middle segments of the plurality of nanostructures; and
a second emitter/collector electrode in electrical contact with the upper segments.

35. The bipolar junction transistor of claim 34, wherein the transistor is a heterojunction bipolar junction transistor.

36. The bipolar junction transistor of claim 34, wherein the base electrode surrounds ones of the middle segments, wherein the second emitter/collector electrode surrounds ones of the upper segments.

37. The bipolar junction transistor of claim 36, wherein the first emitter/collector electrode surrounds ones of the lower segments.
